(19) United States
(12) Patent Application Publication
(10) Pub. No.: US 2026/0107416 A1
(43) Pub. Date: Apr. 16, 2026

(54) COOLING SYSTEM FOR THE LIQUID IMMERSION COOLING OF ELECTRONIC COMPONENTS

(71) Applicant: Wieland-Werke AG, Ulm (DE)

(72) Inventors: Achim GOTTERBARM, Dornstadt (DE); Harald GAIBLER, Rottenacker (DE); Günter FETZER, Staig (DE); Verena OBST, Neu-Ulm (DE); Alexander REUTER, Schelklingen (DE); Heribert RÖSCH, Pfaffenhofen (DE)

(21) Appl. No.: 18/992,737

(22) PCT Filed: Jun. 30, 2023
(86) PCT No.: PCT/EP2023/000042

§ 371 Date: Jan. 9, 2025

(30) Foreign Application Priority Data
Jul. 25, 2022 (DE) 10 2022 002 696.1

(51) Int. Cl. H05K 7/20

(52) U.S. Cl. CPC H05K 7/203; H05K 7/20218; H05K 7/20318; H05K 7/20327

(57) ABSTRACT

A cooling system for the liquid immersion cooling of electronic components, including a vessel filled with two-phase heat transfer fluid, in the liquid phase of which electronic components are immersed. The vessel has a gas space above the surface of the liquid heat transfer fluid, a heat exchanger device in the gas space for forming liquid heat transfer fluid, and a first condenser unit outside the vessel. The first condenser unit is connected by a first feed line to the gas space for mass transfer of gaseous medium and has a first return line for condensed heat transfer fluid to the vessel. A second condenser unit is connected by a second feed line to the first condenser unit for exchange of gaseous medium and has a second return line for condensed heat transfer fluid to the vessel, and the second condenser unit has an outlet for discharging a residual gas.

The invention relates to a cooling system for the liquid immersion cooling of electronic components according to the preamble of claim 1.

Cooling systems for liquid immersion cooling, for example as two-phase immersion cooling systems, are an active cooling solution for electronic components which generate a significant amount of heat during operation. When the components are immersed into a two-phase heat transfer fluid, which generally has a low boiling point, the heat generated by the electronic component can vaporize the surrounding liquid heat transfer fluid, whereby heat is discharged from the electronic component. A condenser device liquefies the gaseous heat transfer fluid which is then returned into the reservoir for cooling.

A two-phase immersion cooling system with a cooling basin is disclosed in the publication U.S. Pat. No. 10,512,192 B2. A condensation chamber, in which the gaseous fluid produced during the cooling process is condensed, is connected to the liquid fluid in the cooling basin. A vapor redirection structure is arranged above the heat-generating electronic components which are located inside the cooling medium in the cooling basin. The vaporized fluid is conducted by means of the vapor redirection structure into the condensation chamber for liquefication. The condensation chamber is located entirely within the cooling basin.

In this context, a cooling system for computer components is disclosed in the publication U.S. Pat. No. 10,477,726 B1. A heat-conducting dielectric heat transfer fluid in the liquid and gaseous phase, which has a boiling point of below 80° C. at atmospheric pressure, is located in a pressure-controlled vessel. Computer components, which are at least partially immersed in the liquid phase of the heat transfer fluid, are arranged in the vessel. The dielectric gas-phase fluid, which has been vaporized by the heat generated by the computer components, is condensed by means of a condenser to form dielectric liquid-phase fluid. The internal pressure is reduced to 650 hPa in the interior of the pressure-controlled vessel. The user can influence the temperature at which the dielectric liquid is vaporized by controlling the pressure in the vessel in which the system operates. This enables a greater cooling capacity to be achieved. The operation of a computer system inside a pressure-controlled vessel at an operating pressure which deviates from the ambient pressure generally requires a structural adaptation of the system as a whole.

A cooling system with a vessel is disclosed in the publication US 2021/0 153 392 A1 which can be filled with two-phase heat transfer fluid as coolant, electronic components being able to be immersed into the liquid phase thereof. The vessel has a gas space above the surface of the liquid heat transfer fluid. A separate external condenser device, which is configured such that it condenses the vapor phase of the heat transfer fluid and returns it as liquid coolant into the vessel with the electronic components, is arranged above the vessel. To this end, the system comprises return and feed lines which are connected both to the condenser device and to the vessel in order to form a heat exchanging loop. The system also comprises a collection vessel which is arranged on the supply line and which is configured such that it collects the condensed liquid heat transfer fluid before the coolant is supplied to the vessel. This accumulator also provides a back-up cooling capacity for the cooling system.

A cooling system for the immersion cooling of electronic components is disclosed in the publication EP 3 453 235 B1, with a pressure-tight tank configured for capturing heat transfer fluid in liquid form in which the electronic equipment is immersed. In addition, a vapor space is present above a surface of the liquid heat transfer fluid. A condenser is arranged outside the pressure-tight tank, wherein the condenser has an inlet which is connected by a riser pipe to the vapor space and is configured to receive heat transfer fluid vapor. In addition, the condenser has a vapor outlet for residual gases which can be closed tightly and a condensate outlet with a condensate return line to the tank. The condensate return line is configured such that heat transfer fluid condensed thereby can flow back from the condensate outlet to the tank. Further condenser tubes can also be already present inside the tank for liquefying the gaseous heat transfer fluid.

The object of the invention is to develop a cooling system for the liquid immersion cooling of electronic components relative to a heat exchanger device for the heat transfer fluid.

The invention is described by the features of claim 1. The further related claims relate to advantageous embodiments and developments of the invention.

The invention encompasses a cooling system for the liquid immersion cooling of electronic components. The cooling system comprises a vessel which can be filled in the interior with two-phase heat transfer fluid, electronic components being able to be immersed in the liquid phase thereof. The vessel has a gas space above the surface of the liquid heat transfer fluid. In addition, the cooling system comprises a heat exchanger device in the gas space of the vessel for the purposes of forming liquid heat transfer fluid. The cooling system also comprises a first condenser unit arranged outside the vessel, wherein the first condenser unit is connected by means of a first feed line to the gas space of the vessel for the mass transfer of gaseous medium and has a first return line for condensed heat transfer fluid to the vessel. According to the invention, a second condenser unit is arranged, said second condenser unit being connected by a second feed line to the first condenser unit for the exchange of gaseous medium and having a second return line for condensed heat transfer fluid to the vessel. The second condenser unit has an outlet, via which a residual gas phase can be discharged.

The vessel can be designed to be pressure-tight. Advantageously, the vessel can be designed as a pressure vessel which can be operated at a negative pressure and/or positive pressure. A greater cooling capacity can be achieved by controlling the pressure in the vessel in which the cooling system operates.

The heat exchanger device in the gas space preferably consists of at least one tube bundle of a plurality of heat exchanger tubes which are arranged relative to one another. A tube bundle can have a plurality of heat exchanger tubes arranged in parallel with one another with two terminal tube bases. The arrangement of the tube bundles or the heat exchanger tubes in the vessel can be implemented symmetrically and also asymmetrically or along inclines relative to the vessel wall.

The heat exchanger tubes are preferably finned tubes which have been produced from smooth tubes which have been subjected to a forming process. They are particularly suitable as components in highly efficient, compact and exceptionally stable heat exchangers with a high heat transfer coefficient. The tube surfaces are optimized to the specific heat transfer needs of the application. A wide selection of materials, which include copper, copper alloys, steels, titanium or titanium alloys, ensures that material suitable for different needs is available for the respective requirements, in particular relative to the durability and deformability.

The two-phase heat transfer fluid, also denoted as coolant, represents the external fluid located in the vessel, the electronic components being immersed in the liquid component thereof. The internal fluid located in the heat exchanger tubes is generally a single-phase heat transfer medium, for example process water, glycol or a thermal oil. However, a two-phase medium can also be used here in combination with a cooling circuit.

In the vessel, the electronic components are arranged in a manner suitable for cooling in a bath of liquid heat transfer fluid and are cooled by the vaporization of the liquid fluid. The proportion of non-condensable gases can be effectively removed from the system before and/or during start-up.

In the embodiment according to the invention, the computer components and immersion cooling devices and the associated power supplies, network connections, wired connections and the like, can be arranged in the vessel, which has an internal pressure deviating from ambient pressure during operation.

In this context, it is also advantageous to combine power, water, vacuum and network connections in a bundle of lines in order to minimize the lead-throughs into the vessel and in order to reduce the risk of leakages, in particular when the system is under a vacuum or positive pressure in operation.

In advantageous embodiments, during operation the vessel is held at up to 200 hPa less than the atmospheric ambient pressure, which contributes to lowering the boiling point of the two-phase heat transfer fluid and thereby to reducing the operating temperature of the computer chips and other components. In several particular embodiments, the pressure-controlled vessel can have an even lower pressure of up to 500 hPa below ambient pressure.

Embodiments according to the invention of the cooling system comprise a vessel which is designed such that a two-phase liquid immersion cooling system is used. The vessel contains a basin consisting of dielectric cooling fluid, a heat exchanger device and further external condenser units connected in series for condensing the dielectric fluid from the gaseous phase to a liquid. The first condenser unit located outside the vessel is intended to condense gaseous heat transfer fluid, which also contains certain proportions of air and water vapor, initially to a proportion of liquid heat transfer fluid which is as large as possible. The residual gas phase passes from this first condenser unit through a second feed line into the second condenser unit. Here the remaining heat transfer fluid is almost completely condensed from the gas phase so that substantially only air and water vapor remain as a residual gas phase. The goal when separating liquid heat transfer fluid is to keep the water vapor in the gas phase by a suitable cooling capacity of the system. This residual gas mixture is discharged from the cooling system via an outlet of the second condenser unit.

In addition, it is also possible to arrange devices for holding computer components and for distributing power from the power supply system to the devices and components which are located inside the vessel. It goes without saying that a plurality of specialized connections are used in order to operate a computer system inside a vessel which is held, for example, at a negative pressure. Several embodiments of the system according to the invention can use a series of fiber-optic interfaces which enable a connectivity in the vessel and to distribute the fibers to the different holding devices for the electronic components. Several embodiments of the vessel can contain sensors for safe operation. These sensors can comprise temperature sensors, fluid level sensors, pressure sensors, position sensors, electric sensors and/or cameras, in order to ensure and to automate the operation of the system.

These systems can comprise, for example, pressure sensors inside the pressure-controlled vessel, which monitor the pressure in order to ensure that no significant leakages are present. Gas sensors which are arranged on the outer face of the pressure-controlled vessel and detect the presence of possibly present dielectric vapor which escapes from the pressure controlled vessel can also.

In addition, the cooling system can advantageously have a control device which is designed to control the operation of the fluid circulation, for example as a function of the temperature of the two-phase heat transfer fluid, and the pressure conditions in the vessel.

Advantageous embodiments of the cooling system according to the invention can be an external frame which stabilizes the vessel and which can be designed from metal profiles in the form of a frame structure and encloses and supports the vessel. The frame structure can be an open design which comprises a cover, side walls and doors for easy access during operation and for maintenance operations. This permits access to the cooling system at on-site locations.

In an advantageous embodiment, a mounting system can be set up by which the electronic components can be transported from the lock device to the operating position for the exchange thereof. A mounting system can consist of robot arms or linear drive devices. With a suitable configuration of the device, an exchange of the components can be carried out via a fully automatic mounting system. Alternatively, gloves can also be arranged at suitable vessel openings for exchanging the electronic components from the lock device to the operating position. This enables mounting by manual access into the interior of the vessel.

In a preferred embodiment of the invention, the feed lines, return lines and/or the outlet can be closed or opened by valves individually or in combination with one another. In order to carry out the method in an appropriate manner, individual valves are opened as required in order to transport away gaseous medium or liquid heat transfer fluid. The supply or discharge can take place cyclically or even in continuous mode. In particular, the valve circuit at the outlet is adapted such that as little as possible heat transfer fluid, or even no heat transfer fluid, exits from the cooling system.

Advantageously, the second condenser unit can be heatable. This operating mode permits the brief heating of the residual gas phase consisting of water vapor and air for pressure compensation. In this operating mode the condensed heat transfer fluid is located in the second return line. The liquid heat transfer fluid can be returned to the vessel by a certain positive pressure or by gravity. The residual gas can also be more easily discharged by means of the heating and the pressure compensation associated therewith relative to the ambient air or positive pressure. With a certain positive pressure relative to the environment, no external air can pass in the opposing direction into the cooling system via the outlet.

In an advantageous embodiment of the invention, a collection vessel can be arranged downstream on the outlet, the residual gas phase being able to be discharged thereby. This vessel also ensures that no air can pass into the cooling system from the environment. The vessel can be an expandable resilient balloon or a bellows which is of variable volume.

Advantageously, a drying unit for separating water vapor from the gas phase can be arranged between the outlet and collection vessel. For example, when the load changes, the pressure level in the entire cooling system changes. If required, via the collection vessel, external air or residual gas can be introduced via the drying unit into the cooling system for pressure compensation. Water vapor is chemically bonded by the drying unit. Silica gel is suitable for such drying units. Further advantageous positions for drying units can also be inside the first and/or second condenser, including the feed lines or return lines thereof.

In an advantageous embodiment of the invention, a vacuum pump can be arranged downstream on the outlet, the residual gas phase being able to be discharged thereby. In this case, the residual gas phase consisting of water vapor and air at the outlet can also have a negative pressure relative to the environment since a flow direction of the residual gas to the outside is always ensured via a vacuum pump.

Advantageously, the first condenser unit can have a greater cooling capacity than the second condenser unit. For example, the cooling capacity of the first condenser unit is at least three times, and further preferably at least five times, as high as that of the second condenser unit. Thus the greatest proportion of heat transfer fluid is already separated in the first condenser unit and the air-water vapor component transported to the second condenser unit is enriched in the gas phase.

Advantageously, the heat exchanger device and the first condenser unit can have a common first supply unit for a first single-phase heat transfer medium for cooling. Thus both units are at a uniform temperature level which is suitable for the separation process of the heat exchanger fluid.

Advantageously, the second condenser unit can have a second supply unit for a second single-phase heat transfer medium for cooling. Thus an independent, different temperature level can be set in the second condenser unit for a further effective separation of the individual phase components.

In an advantageous embodiment of the invention, the second condenser unit can be designed such that it can be operated relative to the first condenser unit at a lower temperature of the single-phase heat transfer medium for cooling. In particular, it has to be taken into account that pressure and temperature conditions which are not below the dew point of the water component are selected in order to keep in the residual gas phase and to be able to dissipate it. The second condenser unit can be optimally used in this pressure temperature range.

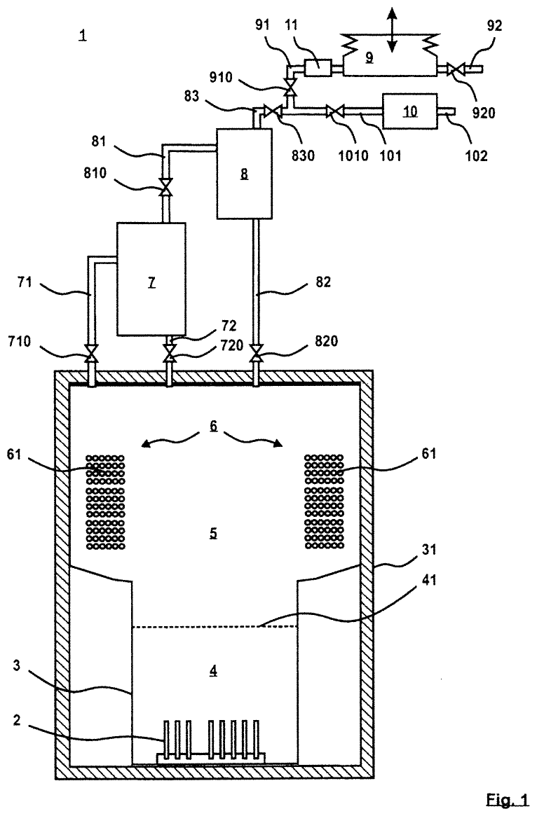

Exemplary embodiments of the invention are explained in more detail by way of the schematic drawing according to FIG. 1.

FIG. 1 shows a schematic view of a cooling system 1 for the liquid immersion cooling of electronic components 2. The cooling system 1 comprises a vessel 3 which can be filled in the interior with a two-phase heat transfer fluid. The two-phase heat transfer fluid represents the external fluid located in the vessel 3, with a liquid heat transfer fluid component 4 in which the electronic components 2 are immersed and a gas space 5 with a gaseous heat transfer fluid component. In the vessel 3, a heat exchanger device 6 is arranged in the gas space 5 of the vessel 3 for forming liquid heat transfer fluid 4.

In this advantageous embodiment, the heat exchanger device 6 in the gas space 5 consists of tube bundles 61 with in each case a plurality of heat exchanger tubes arranged in parallel with one another.

In the FIGURE and in the embodiment shown, the vessel 3 is slightly tapered in the region of the liquid heat transfer fluid 4, by the vessel wall protruding inwardly and opening out only in the gas space 5. The shape of the vessel 3 is supported by a metal profile frame 31. As a result, the vessel 3 is already enclosed by a stabilizing external frame.

A first condenser unit 7 is arranged outside the vessel 3 and thereabove. The first condenser unit 7 is connected for the mass transfer of gaseous medium by means of a first feed line 71 to the gas space 5 of the vessel 3. A first return line 72 for liquefied heat transfer fluid to the vessel 3 is also provided, liquid heat transfer fluid passing via this return line from the first condenser unit 7 back into the vessel 3, driven by gravity. For controlling the mass transfer, a valve 710 is installed in the first feed line 71 and a valve 720 is installed in the first return line 72. Thus a gaseous mixture of heat transfer fluid, air and water vapor is withdrawn cyclically or continually from the vessel 3 via the valve 710 of the first feed line 71. Only liquid heat transfer fluid is returned into the vessel 3 via the valve 720 of the first return line 72.

The gaseous mixture of substances remaining in the first condenser unit 7 is fed to a second condenser unit 8 which is connected by a second feed line 81 to the first condenser unit 7. A valve 810 installed in the second feed line also controls the gas flow. A second return line 82 for further condensed heat transfer fluid leads from the second condenser unit 8 directly to the vessel 3. The return of the condensate formed in the second condenser unit 8 is in turn controlled by a valve 820 installed in the second return line 82. The remaining residual gas phase, which consists merely of air and water vapor after almost complete condensation of the heat transfer fluid, is discharged to the outside via an outlet 83 by means of an outlet valve 830. For the additional separation of water vapor, a drying unit 11 for the separation of water vapor from the gas phase is arranged between the outlet 83 and collection vessel 9.

Depending on the pressure level, the residual gas phase can be discharged directly to the environment. This can be carried out by a heating device in the second condenser unit 8, which sets the pressure level according to the environment by suitably controlled valves.

Alternatively, however, the residual gas phase can also be discharged via a vacuum pump 10. To this end, the outlet 83 is connected via a feed line 101 to a vacuum pump 10 which via a valve controller 1010 controls the residual gas flow to the outside by means of a discharge line 102 of the vacuum pump 10.

Alternatively or additionally, the residual gas phase can also be guided via a feed line 91 with a valve 910 to a collection vessel 9 which can be designed as a bellows of expandable volume for generating a negative pressure. If the valve 910 to the collection vessel 9 is closed during operation, the residual gas can be discharged via the discharge line 92 of the collection vessel 9 when the valve 920 is open.

### LIST OF REFERENCE SIGNS

1 Cooling system
2 Electronic component
3 Vessel
31 Metal profile frame
4 Liquid heat transfer fluid
41 Surface of liquid fluid in vessel
5 Gaseous heat transfer fluid, gas space
6 Heat exchanger device
61 Tube bundle
7 First condenser unit
71 First feed line
710 Valve of first feed line
72 First return line
720 Valve of first return line
8 Second condenser unit
81 Second feed line
810 Valve of second feed line
82 Second return line
820 Valve of second return line
83 Outlet
830 Outlet valve
9 Collection vessel, bellows
91 Feed line—collection vessel
910 Valve of feed line—collection vessel
92 Discharge line—collection vessel
920 Valve of discharge line—collection vessel
10 Vacuum pump
101 Feed line—vacuum pump
1010 Valve of feed line—vacuum pump
102 Discharge line—vacuum pump
11 Drying unit

1. A cooling system for the liquid immersion cooling of electronic components, comprising:
a vessel which can be filled in an interior with two-phase heat transfer fluid, electronic components being able to be immersed in the liquid phase thereof, wherein the vessel has a gas space above a surface of the liquid heat transfer fluid;
a heat exchanger device in the gas space of the vessel for forming liquid heat transfer fluid;
a first condenser unit arranged outside the vessel, wherein the first condenser unit is connected by a first feed line to the gas space of the vessel for mass transfer of gaseous medium and has a first return line for returning condensed heat transfer fluid to the vessel; and
a second condenser unit connected by a second feed line to the first condenser unit for exchange of gaseous medium and having a second return line for returning condensed heat transfer fluid to the vessel,
the second condenser unit having an outlet by which outlet a residual gas phase can be discharged.

2. The cooling system as claimed in claim 1, wherein the first and second feed lines, the first and second return lines and/or the outlet are closed or opened by valves individually or in combination with one another.

3. The cooling system as claimed in claim 1, wherein the second condenser unit is heatable.

4. The cooling system as claimed in claim 1, further including a collection vessel arranged downstream on the outlet for discharge of the residual gas phase.

5. The cooling system as claimed in claim 4, further including a drying unit for separating water vapor from the gas phase, the drying unit being arranged between the outlet and the collection vessel.

6. The cooling system as claimed in claim 1, further including a vacuum pump arranged downstream on the outlet for discharge of the residual gas phase.

7. The cooling system as claimed in claim 1, wherein the first condenser unit has a greater cooling capacity than the second condenser unit.

8. The cooling system as claimed in claim 1, wherein the heat exchanger device and the first condenser unit have a common first supply unit for a first single-phase heat transfer medium for cooling.

9. The cooling system as claimed in claim 8, wherein the second condenser unit has a second supply unit for a second single-phase heat transfer medium for cooling.

10. The cooling system as claimed in claim 9, wherein the second condenser unit is configured for operation relative to the first condenser unit at a lower temperature of the second single-phase heat transfer medium for cooling.
